(19) United States
(12) Patent Application Publication
(10) Pub. No.: US 2026/0018507 A1
(43) Pub. Date: Jan. 15, 2026

(54) HIGH-VOLTAGE APPLICATION OF LOW-VOLTAGE-TOLERANT MULTI-LAYER CAPACITORS

(71) Applicant: Advanced Micro Devices, Inc., Santa Clara, CA (US)

(72) Inventor: Regina Tien Schmidt, San Jose, CA (US)

(21) Appl. No.: 18/771,588

(22) Filed: Jul. 12, 2024

(51) Int. Cl. H01L 23/522

(52) U.S. Cl. CPC H01L 23/5223

(57) ABSTRACT

A system and method for fabricating on-die metal-insulator-metal capacitors capable of supporting relatively high voltage applications and increasing capacitance per area are described. In various implementations, an integrated circuit includes multiple metal-insulator-metal (MIM) capacitors between a first signal net and a second signal net. The integrated circuit includes multiple intermediate floating metal layers (or metal plates) formed between two signal nets. The floating plates have no connection to any power supply reference voltage level used by the integrated circuit. At least one pair of floating metal layers have a via connection between them to reduce the overall insulating thickness of the resulting MIM capacitor.

### BACKGROUND

### Description of the Relevant Art

As both semiconductor manufacturing processes advance and on-die geometric dimensions reduce, semiconductor chips provide more functionality and performance while consuming less space. While many advances have been made, design issues still arise with modern techniques in processing and integrated circuit design that limit potential benefits. For example, as the number and size of passive components used in a design increase, the area consumed by these components also increases. Impedance matching circuits, harmonic filters, decoupling capacitors, bypass capacitors and so on are examples of these components.

Many manufacturing processes use on-die metal-insulator-metal (MIM) capacitors to provide capacitance in both on-die integrated circuits and off-chip integrated passive device (IPD) packages. A MIM capacitor is formed with two parallel metal plates separated by a dielectric layer. Generally speaking, each of the two metal plates and the dielectric layer is parallel to a semiconductor substrate surface. Such MIM capacitors are used in a variety of integrated circuits, including oscillators and phase-shift networks in radio frequency (RF) integrated circuits, as decoupling capacitors to reduce noise in both mixed signal integrated circuits and microprocessors as well as bypass capacitors near active devices in microprocessors to limit the parasitic inductance, and so on. MIM capacitors are also used as memory cells in a dynamic RAM.

Fabricating MIM capacitors is a challenging process. The material selection for the dielectric layer is limited as many of the materials used for the dielectric layer are able to diffuse with the metal layers used for the parallel metal plates. This limited selection can also reduce the capacitance per area that might otherwise be achieved. Further, the on-die region of the integrating circuit using the MIM capacitor can use a relatively high power supply reference voltage level. The MIM capacitor can fail under the high voltage stress, which can render the corresponding circuitry unsatisfactory for its intended purpose.

In view of the above, efficient methods and systems for fabricating on-die metal-insulator-metal capacitors capable of supporting relatively high voltage applications and increasing capacitance per area are desired.

### BRIEF DESCRIPTION OF THE DRAWINGS

FIG. 1 is a generalized diagram of capacitors of an integrated circuit capable of supporting relatively high voltage applications and increasing capacitance per area.

FIG. 2 is a generalized diagram of capacitors of an integrated circuit capable of supporting relatively high voltage applications and increasing capacitance per area.

FIG. 3 is a generalized diagram of capacitors of an integrated circuit capable of supporting relatively high voltage applications and increasing capacitance per area.

FIG. 4 is a generalized diagram of capacitors of an integrated circuit capable of supporting relatively high voltage applications and increasing capacitance per area.

FIG. 5 is a generalized diagram of a method for forming capacitors of an integrated circuit capable of supporting relatively high voltage applications and increasing capacitance per area.

FIG. 6 is a generalized diagram of a computing system with capacitors of an integrated circuit capable of supporting relatively high voltage applications and increasing capacitance per area.

While the invention is susceptible to various modifications and alternative forms, specific implementations are shown by way of example in the drawings and are herein described in detail. It should be understood, however, that drawings and detailed description thereto are not intended to limit the invention to the particular form disclosed, but on the contrary, the invention is to cover all modifications, equivalents and alternatives falling within the scope of the present invention as defined by the appended claims.

### DETAILED DESCRIPTION

In the following description, numerous specific details are set forth to provide a thorough understanding of the present invention. However, one having ordinary skill in the art should recognize that the invention might be practiced without these specific details. In some instances, well-known circuits, structures, and techniques have not been shown in detail to avoid obscuring the present invention. Further, it will be appreciated that for simplicity and clarity of illustration, elements shown in the figures have not necessarily been drawn to scale. For example, the dimensions of some of the elements are exaggerated relative to other elements.

Systems and methods for fabricating on-die metal-insulator-metal capacitors capable of supporting relatively high voltage applications and increasing capacitance per area are contemplated. In various implementations, an integrated circuit includes multiple metal-insulator-metal (MIM) capacitors used in one or more of a variety of types of circuits. An on-die capacitor is formed between two signal nets such as a first signal net and a second signal net. The semiconductor fabrication process (or process) forms between the first signal net and the second signal net, multiple metal layers with adjacent dielectric layers to form multiple metal-insulator-metal (MIM) capacitors. The multiple MIM capacitors combine to form a single equivalent capacitor between the first signal net and the second signal net that provides high tolerance of relatively high voltage stress. In various implementations, the multiple metal layers are floating metal layers with at least one pair of floating metal layers having a via to physically connect (and directly, electrically connect or electrically short) the at least one pair of floating metal layers to one another. Additionally, each individual dielectric layer uses a minimum thickness supported by the process. Therefore, the capacitance between the first signal net and the second signal net increases without increasing the surface area of the floating metal layers. High capacitive density is achieved while also providing high tolerance of relatively high voltage stress.

Typically, using conventional semiconductor fabrication processing, large capacitors are formed to tolerate relatively high voltage stress by increasing the surface area of the floating metal layers. However, this large surface area reduces capacitive density. Using conventional processing, the thickness of the dielectric layer is increased to tolerate the relatively high voltage stress. However, this processing step also reduces capacitive density. Conventional processing also uses low voltage tolerating capacitors in some areas of the integrated circuit and uses separate high voltage tolerating capacitors in other areas of the integrated circuit, which increases cost of production of the integrated circuit. In contrast, using the above multiple MIM capacitors with floating metal layers, minimum dielectric thickness, and at least one via physically connecting at least one pair of floating metal layers provides a configurable low and high voltage tolerant capacitor that can be used across the entire integrated circuit. Thus, high capacitive density is achieved while reducing production costs and still providing protection for high voltage stress conditions.

In various implementations, each individual dielectric layer uses a minimum thickness supported by the process, which increases available capacitance while still achieving high capacitive density. The via that provides the electrical short reduces the overall dielectric thickness of the multiple MIM capacitors, which increases the overall capacitance without increasing surface area of the floating metal layers. Using the minimum thickness for the individual dielectric layers also increases the number of MIM capacitors formed between the first signal net and the second signal net, which increases the overall capacitance between the first signal net and the second signal net. The larger the overall capacitance between the first signal net and the second signal net, the higher the tolerance of relatively high voltage stress provided by relatively high voltage levels on the first signal net and the second signal net.

In some implementations, the two signal nets are power rails charged to two different voltage levels. For example, a first signal net (or first power rail) is charged to a power supply reference voltage level, and a second signal net (or second power rail) is charged to a ground reference voltage level. In other implementations, the two signal nets are two different control signals or two different data signals used by the on-die integrated circuit. As used herein, a “signal net” is a metal layer used as a signal route providing an electrical node for the integrated circuit. As used herein, a “floating metal layer” refers to a metal layer with no connection to a voltage reference level used by the integrated circuit. The floating metal layer is isolated from any voltage reference level used by the integrated circuit.

The floating metal layer is not connected, but rather isolated or disconnected, from any voltage reference level used by the integrated circuit. A signal net includes a metal layer. Similarly, a “floating net” refers to a signal net (or net) with no connection to a voltage reference level used by the integrated circuit. The floating net is isolated from any voltage reference level used by the integrated circuit. As used herein, “connected” refers to a physical connection between two metal layers (or between two signal nets) that provides an electrical connection (an electrical short) when a voltage level is provided to one of the two metal layers (or two signal nets). As used herein, “disconnected” refers to no physical connection between two metal layers (or between two signal nets) and this lack of physical connection prevents a direct electrical connection (an electrical short) when a voltage level is provided to one of the two metal layers (or two signal nets). Although a coupling effect, such as a coupling capacitance, can be present, two metal layers being disconnected have no physical connection between one another that provides a direct electrical connection (an electrical short) between them.

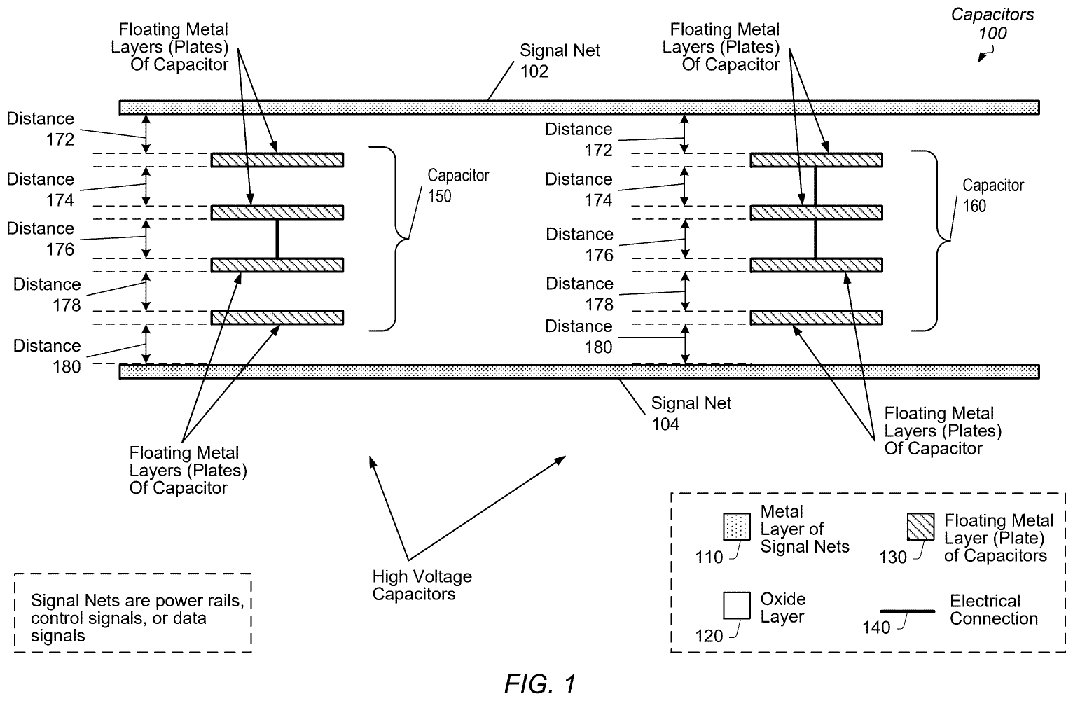

In some implementations, the process forms a third signal net with a dielectric layer between the first signal net and the third signal net where the third signal net is located externally from between the first signal net and the second signal net. In other words, the third signal net is adjacent to the first signal net, but unlike the multiple MIM capacitors, the third signal net is not located between the first signal net and the second signal net. In some implementations, the third signal net is a floating metal layer with no connection to a voltage reference level used by the integrated circuit and is connected to the first voltage reference level. The process forms a fourth signal net and a fifth signal net in a same metal track disconnected from one another and connected to different voltage levels where a floating net is adjacent to each of the fourth signal net and a fifth signal net using a same dielectric layer. Further details of forming multiple MIM capacitors to provide an overall capacitor between signal nets that tolerates relatively high voltage stress and provides high capacitive density are provided in the below description of FIGS. 1-6.

Turning now to FIG. 1, a generalized block diagram is shown of capacitors 100 of an integrated circuit capable of supporting relatively high voltage applications and increasing capacitance per unit area. A semiconductor fabrication process forms multiple intermediate metal layers (or metal plates) using metal layer 130 between two signal nets 102 and 104. The semiconductor fabrication process uses metal plates to form the high voltage metal-insulator-metal (MIM) capacitors 150 and 160 between the two signal nets 102 and 104. The semiconductor fabrication process (or process) forms the MIM capacitors 150 and 160 in the oxide layer 120 between the two signal nets 102 and 104. Each of the MIM capacitors 150 and 160 includes multiple floating metal plates between the two signal nets 102 and 104. The MIM capacitor 150 (or capacitor 150) and the MIM capacitor 160 (or capacitor 160) includes multiple floating metal plates using metal layer 130 and no electrode metal plates connected to one of the two signal nets 102 and 104. The floating plates using metal layer 130 have no connection to any power supply reference voltage level used by the integrated circuit. The process forms an electrical connection 140 between two floating metal plates of the MIM capacitors 150 and 160. The electrical connections 140 include one of a variety of types of vias.

In an implementation, the two signal nets 102 and 104 have static voltage levels over time. In another implementation, the two signal nets 102 and 104 have dynamic voltage levels over time. In some implementations, the two signal nets 102 and 104 are power rails charged to two different voltage levels. In one example, signal net 102 is charged to a power supply reference voltage level, and signal net 104 is charged to a ground reference voltage level. In other implementations, the two signal nets 102 and 104 are two different control signals used by the integrated circuit. In yet other implementations, the two signal nets 102 and 104 are two different data signals used by the integrated circuit.

Although the capacitors 150 and 160 are shown relatively close to one another, it is possible that these capacitors are in different regions of the integrated circuit that use the signal nets 102 and 104. In other implementations, the capacitors 150 and 160 do not share the signal nets 102 and 104. The capacitors 150 and 160 are shown sharing the signal nets 102 and 104 for ease of illustration although not being connected to signal nets 102 and 104. In various implementations, each of the insulating distances 172-180 has an equal distance and each is insufficient to tolerate a potential difference equal to a relatively high-power supply reference voltage level.

Without the electrical connection 140 between the two middle floating metal plates of the MIM capacitors of capacitor 150, capacitor 150 would fail under the relatively high voltage stress. However, adding the electrical connection 140 between two middle floating metal plates using metal layer 130 effectively reduces the insulating material thickness (thickness of oxide layer 120 between floating plates), thus allowing for higher capacitance than if each of the floating metal plates were left unconnected even to one another. For example, without the electrical connection 140 between the two middle floating metal plates of the MIM capacitors of capacitor 150, the overall insulating material thickness (or dielectric thickness) is the sum of the insulating distances 172-180 (or distances 172-180). However, adding the electrical connection 140 between two middle floating metal plates reduces the overall insulating material thickness (or dielectric thickness) to the sum of the distances 172, 174, 178 and 180. Distance 176 is not included in this sum. The configuration of capacitor 150 with the electrical connection 140 between the two middle floating metal plates allows for high-voltage-tolerant usage of capacitor 150 from lower voltage tolerant capacitors.

In a similar manner, without the two electrical connections 140 between the top three floating metal plates of the MIM capacitors of capacitor 160, the overall insulating material thickness (or dielectric thickness) is the sum of the distances 172-180. However, adding the two electrical connections 140 between the top three floating metal plates reduces the overall insulating material thickness (or dielectric thickness) to the sum of the distances 172, 178 and 180. Distances 174 and 176 are not included in this sum. The configuration of capacitor 160 with the two electrical connections 140 between the top three floating metal plates allows for high-voltage-tolerant usage of capacitor 160 from lower voltage tolerant capacitors.

As described earlier, for capacitor 150, the insulating distance is the sum of the distances 172, 174, 178 and 180. Distance 176 is not included in this sum. This insulating distance is greater than the insulating distance of capacitor 160. The insulating distance of capacitor 160 is the sum of the distances 172, 178 and 180. Distances 174 and 176 are not included in this sum. Therefore, the capacitance per unit area of the capacitor 150 is less than the capacitance per unit area of the capacitor 160. The capacitor 160 is capable of supporting relatively high voltage applications while also increasing capacitance per unit area.

In some implementations, the signal net 102 is one signal route using a metal five (Metal 5, or M5) layer and the signal net 104 is signal route using a metal four (Metal 4, or M4) layer. For example, a metal zero (Metal 0, or M0) layer of the semiconductor fabrication process is the lowest (or closest) metal layer formed above a gate region of a transistor. A metal one (Metal 1, or M1) layer is formed above the metal zero layer, and so on. In some designs, each of the signal nets 102 and 104 uses the same conductive material such as metal layer 110. The metal layer 110 uses one of a variety of conductive materials such as copper, a mixture of copper and aluminum, or other. In other designs, signal net 102 uses a different conductive material than what is used for signal net 104.

Although a single oxide layer 120 is shown as formed between the two metal layers used for the signal net 102 and the signal net 104, in some implementations, the process forms one or more insulating dielectric layers. These one or more insulating dielectric layers include at least one inter-level dielectric (ILD) layer. Each of the insulating dielectric layers has a particular dielectric constant and a particular thickness. Thicknesses of metal layers and dielectric layers are measured in the vertical direction when using the orientation shown in FIG. 1. For example, the distances 172-180 are also referred to as the thicknesses 172-180. Using this orientation, the widths of the metal layers 110 and 130 are measured in a direction going into the diagram, whereas the lengths of the metal layers 110 and 130 are measured in the horizontal direction.

The process forms multiple intermediate metal plates that use the metal layer 130 between the two signal nets 102 and 104. The maximum number of metal plates formed between the signal nets 102 and 104 is based on the semiconductor fabrication process used to create the integrated circuit. For example, the semiconductor fabrication process is capable of supporting three, four, or five intermediate metal plates between the signal nets 102 and 104. Another number of intermediate metal plates is also possible and contemplated. In some designs, each of the metal plates uses the same conductive material such as metal layer 130. In an implementation, the metal layer 130 is one of tantalum nitride (TaN) and titanium nitride (TiN) in contrast to copper or a copper and aluminum mixture. In other implementations, the metal layer 130 uses copper, a mixture of copper and aluminum, or other.

In other designs, one or more of the metal plates use a different conductive material than what is used for other metal plates between the signal nets 102 and 104. Similarly, in some designs, each of the metal plates uses the same thickness, whereas, in other designs, one or more of the metal plates use a different thickness than what is used for other metal plates. To increase yield and increase rigidity of the dies of the wafers, in some implementations, the process creates a maximum number of metal plates in particular regions even when the metal plates are not used. In some designs, the maximum number of metal plates is four as shown in capacitors 100.

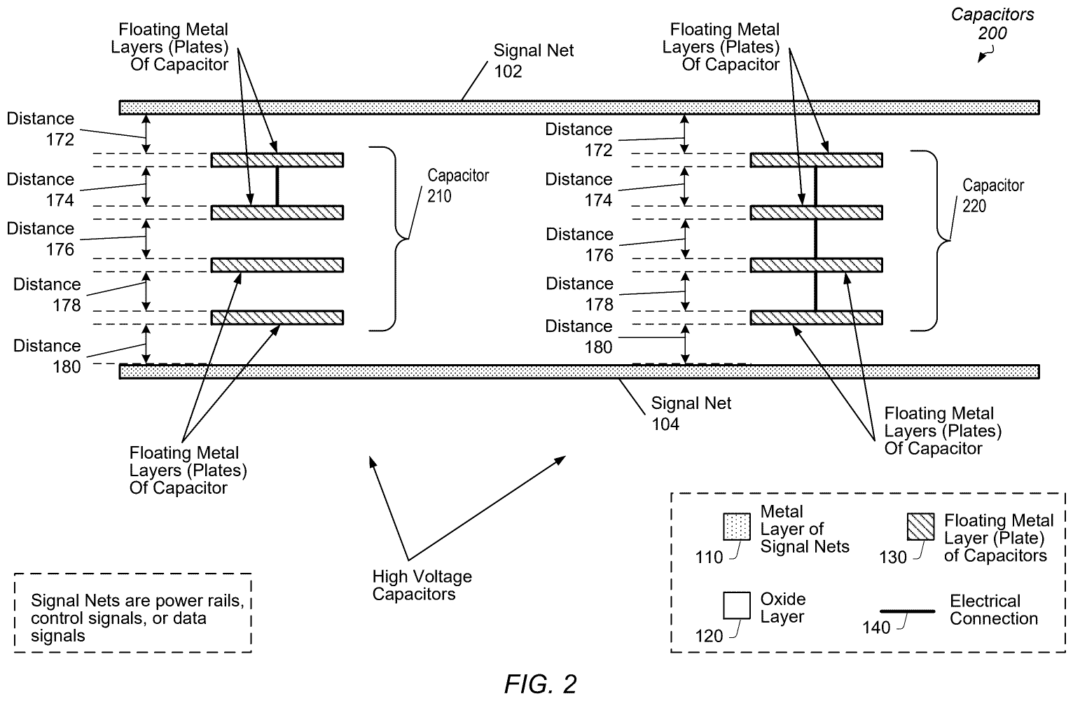

Turning now to FIG. 2, a generalized block diagram is shown of capacitors 200 of an integrated circuit capable of supporting relatively high voltage applications and increasing capacitance per unit area. Signals and materials described earlier are numbered identically. The capacitors 200 includes the high voltage capacitors 210 and 220. Adding the electrical connection 140 between the top two floating metal plates using metal layer 130 of capacitor 210 effectively reduces the insulating material thickness (thickness of oxide layer 120 between floating plates), thus allowing for higher capacitance than if each of the floating metal plates were left unconnected even to one another. With the electrical connection 140 between the top two floating metal plates, the overall insulating material thickness (or dielectric thickness) of capacitor 210 is the sum of the distances 172, 176, 178 and 180. Distance 174 is not included in this sum. However, the capacitance per unit area of capacitor 150 (of FIG. 1) is greater than the capacitance per unit area of capacitor 210.

Adding the electrical connections 140 between each of the floating metal plates using metal layer 130 of capacitor 220 effectively reduces the insulating material thickness (thickness of oxide layer 120 between floating plates), thus allowing for higher capacitance than if each of the floating metal plates were left unconnected even to one another. With the electrical connections 140 between each of the floating metal plates, the overall insulating material thickness (or dielectric thickness) of capacitor 220 is the sum of the distances 172 and 180. Distances 174-178 are not included in this sum.

Without using a different dielectric material with a different dielectric constant and without changing the semiconductor fabrication process, capacitors 150 and 160 (of FIG. 1) and capacitors 210 and 220 provide high voltage capacitors from currently used low voltage capacitors. By utilizing the floating metal plates, the capacitors 150, 160, 210 and 220 provide reliability for high voltage applications without adding additional manufacturing cost. It is noted that other configurations can be used with the electrical connections 140 being placed between different floating metal plates. When adding more electrical connections 140 between different floating metal plates, the overall insulating material thickness (or dielectric thickness) reduces, which increases the overall capacitance and increases the capacitance per unit area.

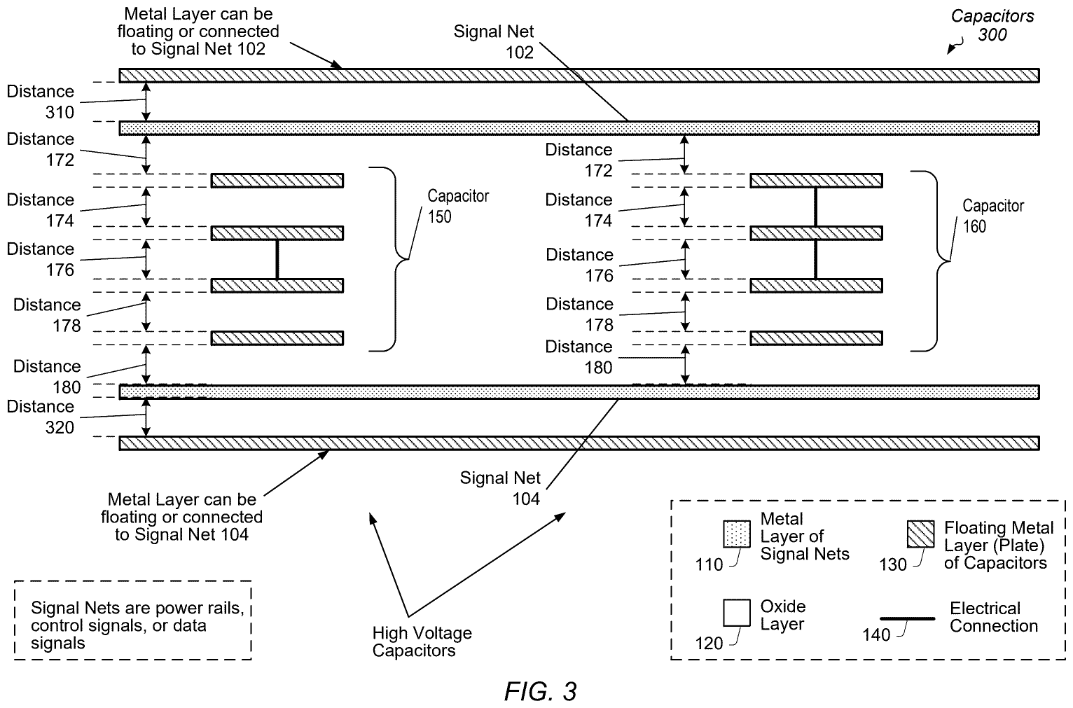

Referring to FIG. 3, a generalized block diagram is shown of capacitors 300 of an integrated circuit capable of supporting relatively high voltage applications and increasing capacitance per unit area. Signals and materials described earlier are numbered identically. The capacitors 300 includes capacitors 150 and 160. Additionally, two additional floating metal plates are placed on other sides of signal nets 102 and 104. These additional floating metal plates are located externally from between the signal nets 102 and 104. In other words, unlike the capacitors 150 and 160, the additional floating metal plates are not located between signal nets 102 and 104. Distance 310 is the separation or thickness between signal net 102 and the top-most metal plate, whereas distance 320 is the separation or distance between signal net 104 and the bottom-most metal plate. In some implementations, the metal layer used for these additional floating metal plates uses metal layer 130, whereas in other implementations, metal layer 110 is used. In yet other implementations, the additional metal plates are electrically connected (electrically shorted) to signal nets 102 and 104. For example, the top-most floating metal plate is connected to signal net 102 and the bottom-most floating metal plate is connected to signal net 104. When multiple metal layers of conductive terminals are available such as the additional floating metal plates, the fabrication process can choose to connect to any and not necessarily the outer layers to form a capacitor, such that one or more of the outer-most terminal is left floating or disconnected. It is possible and contemplated that these additional floating metal plates (which are later connected or left disconnected) are also used with capacitors 210 and 220 (of FIG. 2) and other combinations of high voltage capacitors built from low voltage capacitors using the electrical connections 140 and floating metal plates of the metal layer 130.

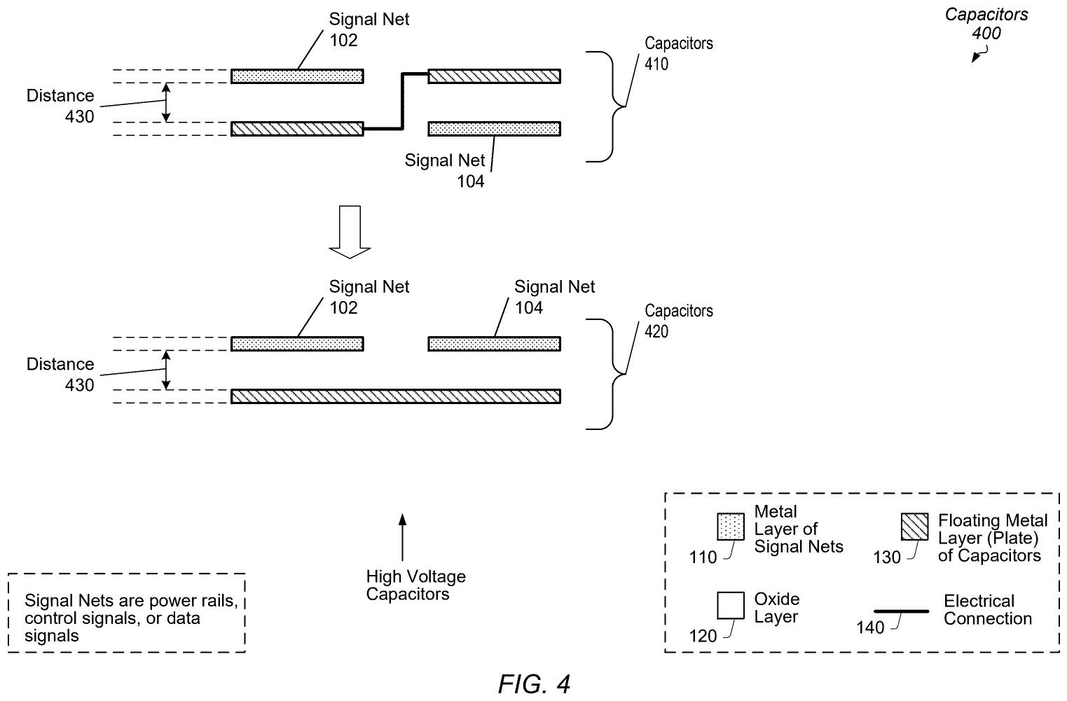

Turning now to FIG. 4, a generalized block diagram is shown of capacitors 400 of an integrated circuit capable of supporting relatively high voltage applications and increasing capacitance per unit area. Signals and materials described earlier are numbered identically. The capacitors 400 includes capacitors 410 and 420. Capacitors 410 include signal net 102 with a floating metal plate in the same metal track. Similarly, signal net 104 has a floating metal plate in a same metal track. The two floating metal plates have an electrical connection 140, which includes forming a via. In contrast, capacitors 420 include the signal net 102 in the same metal track as signal net 104. The same floating metal plate is adjacent to each of the signal nets 102 and 104 with the same distance 430 used in capacitors 410. Capacitors 420 provide increased total capacitance compared to capacitors 410 due to reduction of using vias (electrical connections 140). The vias cut holes in the capacitors and takes away from total usable capacitor area. The topology of capacitors 420 can be extended to multi-layer capacitors and is not limited to 2-layer capacitors.

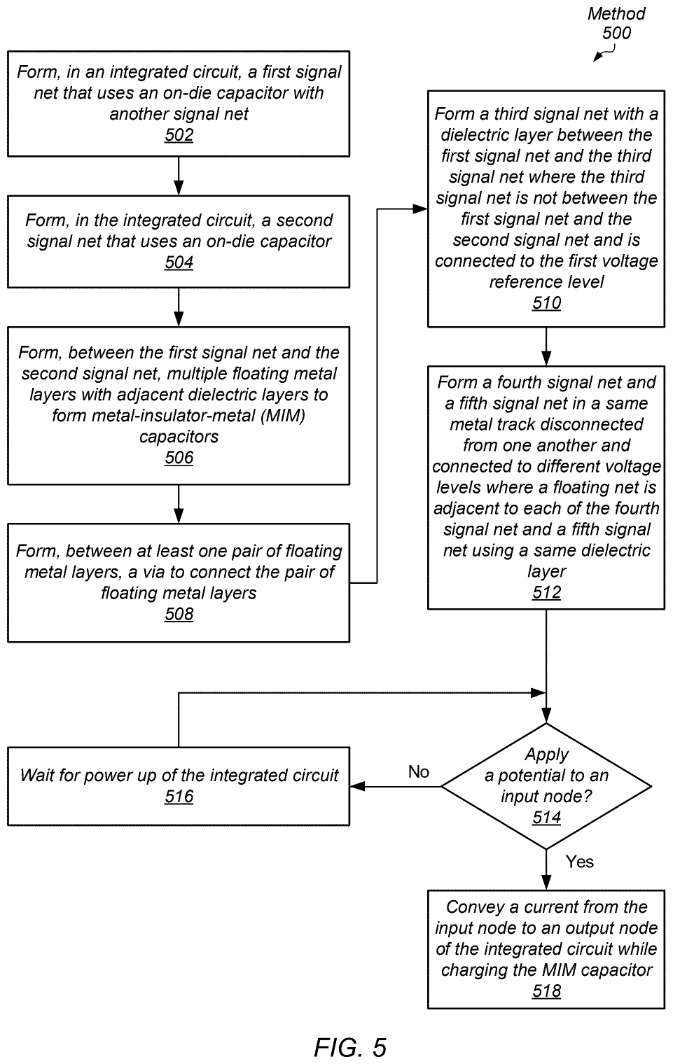

Turning to FIG. 5, a generalized block diagram of a method 500 for forming capacitors of an integrated circuit capable of supporting relatively high voltage applications and increasing capacitance per area is shown. For purposes of discussion, the steps in this implementation are shown in sequential order. However, in other implementations some steps occur in a different order than shown, some steps are performed concurrently, some steps are combined with other steps, and some steps are absent. Typically, an on-die capacitor is formed between two signal nets. In some implementations, the two signal nets are power rails charged to two different voltage levels. A first signal net (or first power rail) is charged to a power supply reference voltage level, and a second signal net (or second power rail) is charged to a ground reference voltage level. In other implementations, the two signal nets are two different control signals or two different data signals used by the on-die integrated circuit. In one example, the first signal net is a metal four (M4) layer and the second signal net is a metal five (M5) layer. In one example, the first signal net is equivalent to signal net 104 and the second signal net is equivalent to the signal net 102 (of FIGS. 1-4). One or more insulating dielectric layers are formed between the two metal layers used for the first signal net and the second signal net. These one or more insulating dielectric layers include at least one inter-level dielectric (ILD). A semiconductor fabrication process (or process) forms, in an integrated circuit, the first signal net that uses an on-die capacitor with another signal net (block 502).

To form the first signal net, the process forms a metal layer on top of an oxide layer, such as the inter-level dielectric (ILD). The ILD is used to insulate metal layers, which are used for interconnects. In some implementations, the ILD is silicon dioxide. In other implementations, the ILD is one of a variety of low-k dielectrics containing carbon or fluorine. The low-k dielectrics provide a lower capacitance between the metal layers, and thus, reduce performance loss, power consumption, and cross talk between interconnect routes. A chemical mechanical planarization (CMP) step is used to remove unwanted ILD and to polish the remaining ILD. The CMP step achieves a near-perfect flat and smooth surface upon which further layers are built. Following, the process deposits the metal layer to be used as the first signal net. The metal layer is one of a variety of conductive materials such as copper, a mixture of copper and aluminum, and so on.

In some implementations, the process uses a dual damascene process to form the metal layer of the first signal net, whereas, in other implementations, the process uses a single damascene process. These and other techniques are contemplated. When the process uses copper for the first signal net, the process deposits a liner on the ILD before forming the metal layer. The liner uses a tantalum (Ta) based barrier material to prevent the copper from diffusing into the ILD and to act as an adhesion layer for the copper. Next, the process deposits a thin copper seed layer by physical vapor diffusion (PVD) followed by electroplating of copper. Afterward, the process polishes the excess copper metal and deposits a capping layer typically SiN (silicon mononitride). The process forms an additional oxide layer on top of the first signal net of a controlled thickness. In various implementations, the thickness of the oxide layer on top of the first signal net is at least an order of magnitude greater than the thickness of a thin gate silicon dioxide layer formed for active devices such as transistors. The process deposits the oxide layer using a combination of gasses such as dichlorosilane or silane with oxygen precursors, such as oxygen and nitrous oxide, typically at pressures from a few millitorr to a few torr.

The process forms, in the integrated circuit, a second signal net that uses an on-die capacitor (block 504). The process forms, between the first signal net and the second signal net, multiple floating metal layers with adjacent dielectric layers to form multiple metal-insulator-metal (MIM) capacitors (block 506). The process forms, between at least one pair of floating metal layers, a via to connect the pair of floating metal layers (block 508). The process forms a third signal net with a dielectric layer between the first signal net and the third signal net where the third signal net is located externally from between the first signal net and the second signal net and is connected to the first voltage reference level (block 510). In other words, the third signal net is adjacent to the first signal net, but unlike the multiple MIM capacitors, the third signal net is not located between the first signal net and the second signal net.

The process forms a fourth signal net and a fifth signal net in a same metal track disconnected from one another and connected to different voltage levels where a floating net is adjacent to each of the fourth signal net and a fifth signal net using a same dielectric layer (block 512). If a potential is not applied to an input node of the integrated circuit (“no” branch of the conditional block 514), then the integrated circuit waits for power up (block 516). However, if a potential is applied to the input node of the integrated circuit (“yes” branch of the conditional block 514), then the circuitry of the integrated circuit conveys a current from the input node to an output node of the integrated circuit while charging the MIM capacitor (block 518).

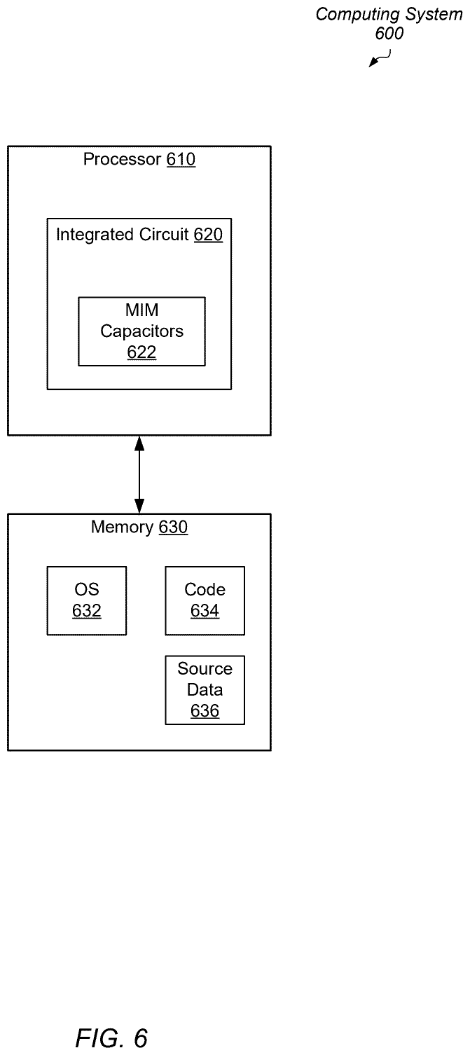

Referring to FIG. 6, one implementation of a computing system 600 is shown. The computing system 600 includes the processor 610 and the memory 630. Interfaces, such as a memory controller, a bus or a communication fabric, one or more phased locked loops (PLLs) and other clock generation circuitry, a power management unit, and so forth, are not shown for ease of illustration. It is understood that in other implementations, the computing system 600 includes one or more of other processors of a same type or a different type than processor 610, one or more peripheral devices, a network interface, one or more other memory devices, and so forth. In some implementations, the functionality of the computing system 600 is incorporated on a system on chip (SoC). In other implementations, the functionality of the computing system 600 is incorporated on a peripheral card inserted in a motherboard. The computing system 600 is used in any of a variety of computing devices such as a server computer, a desktop computer, a tablet computer, a laptop, a smartphone, a smartwatch, a gaming console, a personal assistant device, and so forth.

The processor 610 includes hardware such as circuitry. For example, processor 610 includes at least one integrated circuit 620, which utilizes MIM capacitors 622. The integrated circuit 620 uses the MIM capacitors 622 for a variety of applications such as decoupling two signal nets from one another, smoothing or stabilizing the current and voltage output of power supplies and voltage regulators, adjusting frequency tuning circuitry, reconstructing receiving signals from transmission lines, and so on. Other examples of applications that use the MIM capacitors 622 are oscillators and phase-shift networks in radio frequency (RF) integrated circuits, bypass capacitors near active devices in microprocessors to limit the parasitic inductance, memory cell data storage in dynamic RAM, and so on. The MIM capacitors 622 are capable of supporting relatively high voltage applications and increasing capacitance per area. For example, one or more of the MIM capacitors 622 instantiated in the integrated circuit 620 use configurations as shown earlier for capacitors in FIGS. 1-4.

In various implementations, the processor 610 includes one or more processing units. In some implementations, each of the processing units includes one or more processor cores capable of general-purpose data processing, and an associated cache memory subsystem. In such an implementation, processor 610 is a central processing unit (CPU). In another implementation, the processing cores are compute units, each with a highly parallel data microarchitecture with multiple parallel execution lanes and an associated data storage buffer. In such an implementation, the processor 610 is a graphics processing unit (GPU), a digital signal processor (DSP), or other.

In some implementations, the memory 630 includes one or more of a hard disk drive, a solid-state disk, other types of flash memory, a portable solid-state drive, a tape drive and so on. The memory 630 stores an operating system (OS) 632, one or more applications represented by code 634, and at least source data 636. Memory 630 is also capable of storing intermediate result data and final result data generated by the processor 610 when executing a particular application of code 634. Although a single operating system 632 and a single instance of code 634 and source data 636 are shown, in other implementations, another number of these software components are stored in memory 630. The operating system 632 includes instructions for initiating the boot up of the processor 610, assigning tasks to hardware circuitry, managing resources of the computing system 600 and hosting one or more virtual environments.

Each of the processor 610 and the memory 630 includes an interface unit for communicating with one another as well as any other hardware components included in the computing system 600. The interface units include queues for servicing memory requests and memory responses, and control circuitry for communicating with one another based on particular communication protocols. The communication protocols determine a variety of parameters such as supply voltage levels, power-performance states that determine an operating supply voltage and an operating clock frequency, a data rate, one or more burst modes, and so on.

It is noted that one or more of the above-described implementations include software. In such implementations, the program instructions that implement the methods and/or mechanisms are conveyed or stored on a computer readable medium. Numerous types of media which are configured to store program instructions are available and include hard disks, floppy disks, CD-ROM, DVD, flash memory, Programmable ROMs (PROM), random access memory (RAM), and various other forms of volatile or non-volatile storage. Generally speaking, a computer accessible storage medium includes any storage media accessible by a computer during use to provide instructions and/or data to the computer. For example, a computer accessible storage medium includes storage media such as magnetic or optical media, e.g., disk (fixed or removable), tape, CD-ROM, or DVD-ROM, CD-R, CD-RW, DVD-R, DVD-RW, or Blu-Ray. Storage media further includes volatile or non-volatile memory media such as RAM (e.g. synchronous dynamic RAM (SDRAM), double data rate (DDR, DDR2, DDR3, etc.) SDRAM, low-power DDR (LPDDR2, etc.) SDRAM, Rambus DRAM (RDRAM), static RAM (SRAM), etc.), ROM, Flash memory, non-volatile memory (e.g. Flash memory) accessible via a peripheral interface such as the Universal Serial Bus (USB) interface, etc. Storage media includes microelectromechanical systems (MEMS), as well as storage media accessible via a communication medium such as a network and/or a wireless link.

Additionally, in various implementations, program instructions include behavioral-level descriptions or register-transfer level (RTL) descriptions of the hardware functionality in a high-level programming language such as C, or a design language (HDL) such as Verilog, VHDL, or database format such as GDS II stream format (GDSII). In some cases, the description is read by a synthesis tool, which synthesizes the description to produce a netlist including a list of gates from a synthesis library. The netlist includes a set of gates, which also represent the functionality of the hardware including the system. The netlist is then placed and routed to produce a data set describing geometric shapes to be applied to masks. The masks are then used in various semiconductor fabrication steps to produce a semiconductor circuit or circuits corresponding to the system. Alternatively, the instructions on the computer accessible storage medium are the netlist (with or without the synthesis library) or the data set, as desired. Additionally, the instructions are utilized for purposes of emulation by a hardware-based type emulator from such vendors as Cadence®, EVER, and Mentor Graphics®.

Although the implementations above have been described in considerable detail, numerous variations and modifications will become apparent to those skilled in the art once the above disclosure is fully appreciated. It is intended that the following claims be interpreted to embrace all such variations and modifications.

What is claimed is:

1. An integrated circuit comprising:
a first metal layer connected to a first voltage reference level;
a second metal layer connected to a second voltage reference level;
a plurality of metal layers with adjacent dielectric layers between the first metal layer and the second metal layer, wherein each of the plurality of metal layers:
is a floating metal layer; and
is used to form a metal-insulator-metal (MIM) capacitor of a plurality of MIM capacitors between the first metal layer and the second metal layer.

2. The integrated circuit as recited in claim 1, further comprising a first via between a first pair of metal layers of the plurality of metal layers.

3. The integrated circuit as recited in claim 2, further comprising a second via between a second pair of metal layers of the plurality of metal layers.

4. The integrated circuit as recited in claim 2, wherein a sum of thicknesses of dielectric layers between adjacent metal layers disconnected from one another between the first metal layer and the second metal layer is less than a threshold.

5. The integrated circuit as recited in claim 2, further comprising a third metal layer with a dielectric layer between the first metal layer and the third metal layer, wherein the third metal layer is not located between the first metal layer and the second metal layer and is a floating metal layer.

6. The integrated circuit as recited in claim 2, further comprising a third metal layer with a dielectric layer between the first metal layer and the third metal layer, wherein the third metal layer is not located between the first metal layer and the second metal layer and is connected to the first voltage reference level.

7. The integrated circuit as recited in claim 1, further comprising a third metal layer and fourth metal layer in a same metal track disconnected from one another and connected to different voltage levels, wherein a floating metal layer is adjacent to each of the third metal layer and the fourth metal layer using a same dielectric layer.

8. A method comprising:
forming a first metal layer connected to a first voltage reference level of an integrated circuit;
forming a second metal layer connected to a second voltage reference level of the integrated circuit;
forming a plurality of metal layers with adjacent dielectric layers between the first metal layer and the second metal layer, wherein each of the plurality of metal layers:
is a floating metal layer; and
is used to form a metal-insulator-metal (MIM) capacitor of a plurality of MIM capacitors between the first metal layer and the second metal layer.

9. The method as recited in claim 8, further comprising forming a first via between a first pair of metal layers of the plurality of metal layers.

10. The method as recited in claim 9, further comprising forming a second via between a second pair of metal layers of the plurality of metal layers.

11. The method as recited in claim 9, wherein a sum of thicknesses of dielectric layers between adjacent metal layers disconnected from one another between the first metal layer and the second metal layer is less than a threshold.

12. The method as recited in claim 9, further comprising a third metal layer with a dielectric layer between the first metal layer and the third metal layer, wherein the third metal layer is not located between the first metal layer and the second metal layer and is a floating metal layer.

13. The method as recited in claim 9, further comprising forming a third metal layer with a dielectric layer between the first metal layer and the third metal layer, wherein the third metal layer is not located between the first metal layer and the second metal layer and is connected to the first voltage reference level.

14. The method as recited in claim 13, further comprising forming a third metal layer and fourth metal layer in a same metal track disconnected from one another and connected to different voltage levels, wherein a floating net is adjacent to each of the third metal layer and the fourth metal layer using a same dielectric layer.

15. A computing system comprising:
a memory configured to store instructions of one or more tasks and source data to be processed by the one or more tasks;
an integrated circuit configured to execute the instructions using the source data, wherein the integrated circuit comprises:
a first metal layer connected to a first voltage reference level;
a second metal layer connected to a second voltage reference level;
a plurality of metal layers with adjacent dielectric layers between the first metal layer and the second metal layer, wherein each of the plurality of metal layers:
is a floating metal layer; and
is used to form a metal-insulator-metal (MIM) capacitor of a plurality of MIM capacitors between the first metal layer and the second metal layer.

16. The computing system as recited in claim 15, wherein a first via is between a first pair of metal layers of the plurality of metal layers.

17. The computing system as recited in claim 16, wherein a second via is between a second pair of metal layers of the plurality of metal layers.

18. The computing system as recited in claim 16, wherein a sum of thicknesses of dielectric layers between adjacent metal layers disconnected from one another between the first metal layer and the second metal layer is less than a threshold.

19. The computing system as recited in claim 16, wherein the integrated circuit further comprises a third metal layer with a dielectric layer between the first metal layer and the third metal layer, wherein the third metal layer is not located between the first metal layer and the second metal layer and is a floating metal layer.

20. The computing system as recited in claim 16, wherein the integrated circuit further comprises a third metal layer with a dielectric layer between the first metal layer and the third metal layer, wherein the third metal layer is not located between the first metal layer and the second metal layer and is connected to the first voltage reference level.
